(19) United States
(12) Patent Application Publication
(10) Pub. No.: US 2022/0127711 A1
(43) Pub. Date: Apr. 28, 2022

(54) FRAME-INTEGRATED MASK

(71) Applicant: TGO Tech. Corporation, Yongin-si (KR)

(72) Inventor: Taek Yong JANG, Seongnam-si (KR)

(21) Appl. No.: 17/520,212

(22) Filed: Nov. 5, 2021

Related U.S. Application Data
(62) Division of application No. 16/618,350, filed on Nov. 30, 2019.

(30) Foreign Application Priority Data
May 31, 2017 (KR) 10-2017-0067396

(51) Int. Cl. C23C 14/04; H01L 51/00

(52) U.S. Cl. CPC C23C 14/042; H01L 51/0011

(57) ABSTRACT

The present invention relates to a frame-integrated mask. The frame-integrated mask according to the present invention is used in a process of forming pixels on a silicon wafer, and includes a mask including a mask pattern, and a frame connected to at least a part of a region of the mask excluding the region in which the mask pattern is formed. The mask has a shape corresponding to the silicon wafer and is integrally connected to the frame.

### CROSS-REFERENCE TO RELATED APPLICATIONS

This application is a Divisional of U.S. application Ser. No. 16/618,350, filed Nov. 30, 2019, which claims priority of International Patent Application No. PCT/KR2018/004272, filed on Apr. 12, 2018, which claims priority of Korean Patent Application No. KR 10-2017-0067396, filed on May 31, 2017, the disclosures of which are incorporated by reference in their entirety.

### TECHNICAL FIELD

The present invention relates to a frame-integrated mask. More specifically, the present invention relates to a frame-integrated mask which is used for forming pixels on a silicon wafer and has a mask formed integrally with a frame, thereby preventing deformation of the mask and realizing high resolution.

### BACKGROUND ART

Recently, research is being carried out on an electroforming method a thin film manufacturing method. The electroforming method is performed by dipping an anode body and a cathode body in an electrolyte and electrodepositing a metal thin film on the surface of the cathode body by applying electricity, and thus ultra-thin films may be manufactured in a large quantity.

As a pixel deposition technique in an organic light-emitting diode (OLED) manufacturing process, a fine metal mask (FMM) method for positioning a thin metal mask (or a shadow mask) in contact with or very close to a substrate and depositing an organic material at desired locations is commonly used.

In a conventional OLED manufacturing process, after a mask thin film is prepared, a mask is welded and fixed to an OLED pixel deposition frame and then is used. In the fixing process, there is a problem in that the mask of a large area is not well aligned. Also, in the process of welding and fixing the mask to the frame, there is a problem in that the mask sags or twists with the load since the mask film is too thin and has a large area.

In an ultra-high-resolution OLED manufacturing process, small defects of several μm may lead to pixel deposition failure, and thus there is a need to develop technology that is capable of preventing deformation of a mask, such as sagging or twisting of a mask, and clearly aligning the mask.

Recently, a microdisplay which is applied to a virtual reality (VR) device has drawn attention. A microdisplay is required to provide a much smaller screen size than those of the existing displays and still realize high quality within the small screen. Therefore, smaller mask patterns than those of a mask used in the existing high-definition OLED manufacturing process and a finer alignment of the mask before a pixel deposition process are required.

### Technical Problem

Therefore, the present invention is devised to solve the above-mentioned problems of the related art and provides a frame-integrated mask capable of realizing ultra-high-resolution pixels of a microdisplay.

Moreover, the present invention provides a frame-integrated mask capable of enhancing stability of pixel deposition by allowing a mask to be clearly aligned.

### Technical Solution

The present invention provides a frame-integrated mask which is used in a process of forming pixels on a silicon wafer, the frame-integrated mask including: a mask including a mask pattern; and a frame connected to at least a part of a region of the mask excluding a region in which the mask pattern is formed, wherein the mask has a shape corresponding to the silicon wafer and is integrally connected to the frame.

The shape of the mask may be circular.

The frame may include: a connecting frame connected to the mask; and a support frame integrally connected to a lower portion of the connecting frame and supporting the mask and the connecting frame.

The connecting frame may have a circular ring shape.

A width of the mask adhered to the connecting frame may be constant along an outer circumferential direction of the mask.

The mask may be integrally connected to the frame in a state in which a tensile force is exerted on an outer circumference of the mask in a direction of the frame.

The mask and the frame may be made of an Invar material or a Super Invar material.

The frame-integrated mask is used as a fine metal mask (FMM) for organic light-emitting diode (OLED) pixel deposition, the mask is attached to a silicon wafer substrate on which pixels are to be deposited, and the frame is fixedly installed inside an OLED pixel deposition apparatus.

A resolution of the mask pattern may be higher than at least 2000 pixels per inch (PPI).

A width of the mask pattern gradually increases from an upper portion to a lower portion.

### Advantageous Effects

According to the present invention with the above-described configuration, it is possible to realize ultra-high-resolution pixels of a microdisplay.

In addition, according to the present invention, it is possible to improve stability of pixel deposition by allowing a mask to be clearly aligned.

### BRIEF DESCRIPTION OF THE DRAWINGS

FIG. 1 is a schematic diagram showing an organic light-emitting diode (OLED) pixel deposition apparatus using a conventional fine metal mask (FMM).

FIG. 2 is a schematic diagram showing a frame-integrated mask according to one embodiment of the present invention.

FIG. 3 is a schematic diagram showing mask patterns according to one embodiment of the present invention.

FIG. 4 is a vertical cross-sectional view taken along line A-A′ of FIG. 2.

FIGS. 5A-5C and 6A-6G are schematic diagrams showing a process of manufacturing a frame-integrated mask according to one embodiment of the present invention.

FIGS. 7A-7D and 8A-8G are schematic diagrams showing a process of manufacturing a frame-integrated mask according to another embodiment of the present invention.

FIG. 9 is a schematic diagram illustrating an OLED pixel deposition apparatus to which the frame-integrated mask of FIG. 2 is applied.

FIG. 10 is a schematic diagram showing a state in which a frame-integrated mask in accordance with another embodiment of the present invention is applied to an OLED pixel deposition apparatus.

### DESCRIPTION OF REFERENCE NUMERALS

10, 10′: Frame-integrated mask
20: Mask, Plated film
20a: Mask body portion
20b: Mask support portion
30: Frame
31: Connecting frame
35: Support frame
40: Mother plate
100: Conventional mask, shadow mask, find metal mask (FMM)
200, 300: OLED pixel deposition apparatus
DP: display pattern
PP: pixel pattern, mask pattern

### MODE FOR INVENTION

The following detailed descriptions of the invention will be made with reference to the accompanying drawings illustrating specific embodiments of the invention by way of example. These embodiments will be described in detail such that the invention can be carried out by one of ordinary skill in the art. It should be understood that various embodiments of the invention are different, but are not necessarily mutually exclusive. For example, a specific shape, structure, and characteristic of an embodiment described herein may be implemented in another embodiment without departing from the scope of the invention. In addition, it should be understood that a position or placement of each component in each disclosed embodiment may be changed without departing from the scope of the invention. Accordingly, there is no intent to limit the invention to the following detailed descriptions. The scope of the invention is defined by the appended claims and encompasses all equivalents that fall within the scope of the appended claims. In the drawings, like reference numerals denote like functions, and the dimensions such as lengths, areas, and thicknesses of elements may be exaggerated for clarity.

Hereinafter, to allow one of ordinary skill in the art to easily carry out the invention, embodiments of the present invention will be described in detail with reference to the accompanying drawings.

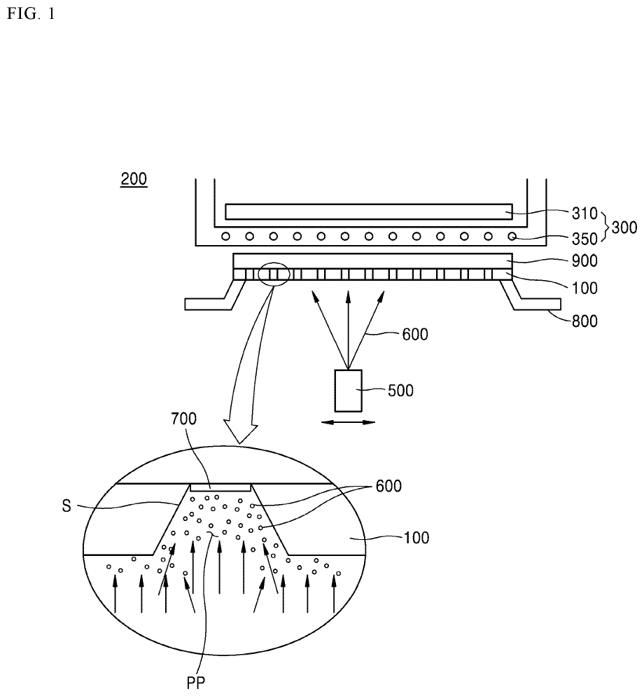

FIG. 1 is a schematic diagram showing an organic light-emitting diode (OLED) pixel deposition apparatus 200 using a conventional fine metal mask (FMM) 100.

Referring to FIG. 1, in general, the OLED pixel deposition apparatus 200 includes a magnet plate 200 containing a magnet 310 and having cooling water lines 350 disposed therein and a deposition source supply 500 for supplying an organic source 600 from below the magnet plate 300.

A target substrate 900, on which the organic material source 600 is to be deposited, e.g., a glass substrate, may be provided between the magnet plate 300 and the deposition source supply 500. The FMM 100 for enabling deposition of the organic material source 600 per pixel may be positioned in contact with or very close to the target substrate 900. The magnet 310 may generate a magnetic field and the FMM 100 is brought in contact with or very close to the target substrate 900 due to the attraction by the magnetic field.

The FMM 200 needs to be aligned before being in contact with the target substrate 900. One mask or a plurality of masks may be coupled to the frame 800. The frame 800 may be fixedly installed in the OLED pixel deposition apparatus 200 and the mask may be coupled to the frame 800 through separate attachment and welding processes.

The deposition source supply 500 may supply the organic material source 600 while horizontally reciprocating, and the organic material source 600 supplied from the deposition source supply 500 may pass through patterns PP of the FMM mask 100 and be deposited on a surface of the target substrate 900. The organic material source 600 deposited through the patterns of the FMM mask 100 may serve as pixels 700 of an OLED.

To prevent non-uniform deposition of pixels 700 due to shadow effect, the pattern of the FMM mask 100 may have a sloped shape S [or a tapered shape S]. The organic material source 600 passing through the patterns in diagonal directions along sloped surfaces may also contribute to deposition of the pixels 700 and thus the pixels 700 may be deposited to a uniform thickness.

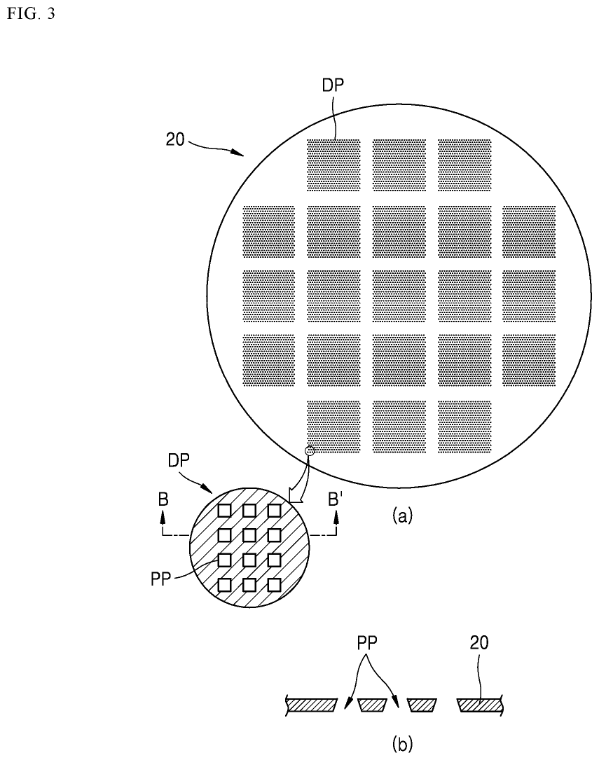

In FIG. 3, the FMM 200 may be manufactured as stick type or plate type and be used in a pixel deposition process for the target substrate 900 of a large area. However, a microdisplay, which is recently applied to a virtual reality (VR) device, may be used in a pixel deposition process for a silicon wafer, rather than for the target substrate 900 of a large area. The micro display has a screen that is about 1 to 2 inches smaller than the size of the large area substrate because a screen is positioned directly in front of an eye of a user. Moreover, implementation of higher resolution is required since the screen is positioned closely in front of the eye of the user.

Accordingly, the present invention is directed to provide a frame-integrated mask which, rather than being used in a pixel formation process for the target substrate 900 of a large area, allows for a pixel formation process on a silicon wafer of 200 mm, 300 mm, or 450 mm such that ultra-high-resolution pixels are formed.

For example, currently, quad high definition (QHD) image quality is 500 to 600 pixels per inch (PPI), and a size of each pixel is about 30 to 50 μm, and a 4K UHD or 8K UHD image quality has a resolution of up to 860 PPI or up to 1600 PPI, which is higher than the QHD image quality. A microdisplay directly applied to a VR device or a microdisplay inserted into a VR device is aimed at realizing ultra-high resolution of approximately 2000 PPI or above and has a pixel size of about 5 to 10 μm. In the case of a silicon waver, a finer and more precise process is possible compared to a glass substrate by utilizing technologies developed in a semiconductor process, and hence the silicon wafer may be employed as a substrate of a high-resolution microdisplay. In addition, the present invention is characterized by a frame-integrated mask that allows for formation of pixels on the silicon wafer.

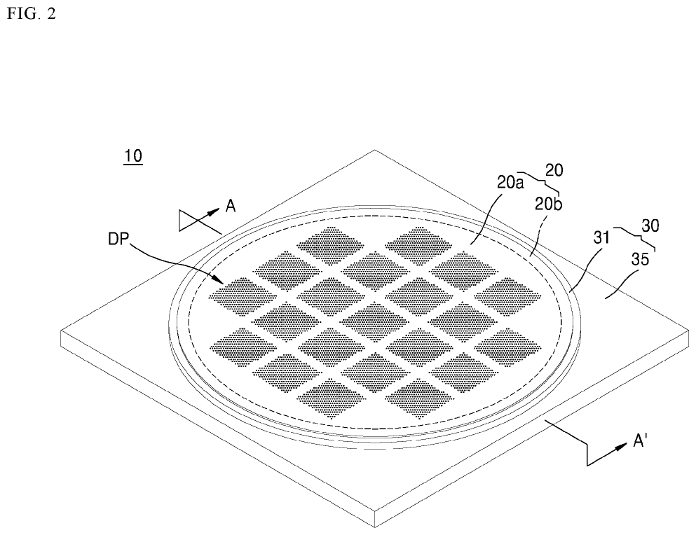

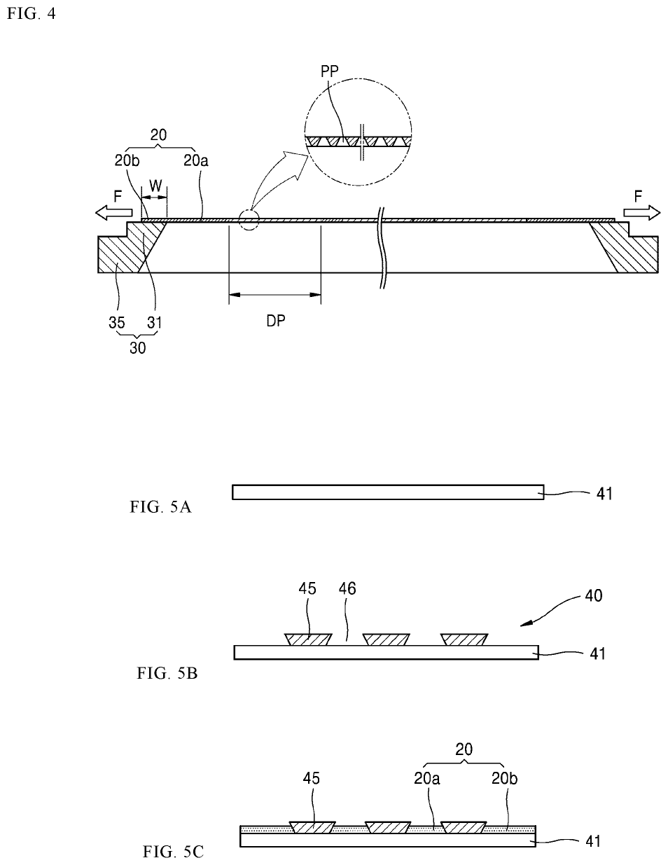

FIG. 2 is a schematic diagram showing a frame-integrated mask 10 according to one embodiment of the present invention. FIG. 3 is a schematic diagram showing mask patterns DP and PP according to one embodiment of the present invention, in which (a) of FIG. 3 is a plan view of the mask 20 of FIG. 2 and (b) of FIG. 3 is an enlarged vertical cross-sectional view taken along line B-B′ of (a) of FIG. 3. FIG. 4 is a vertical cross-sectional view taken along line A-A′ of FIG. 2.

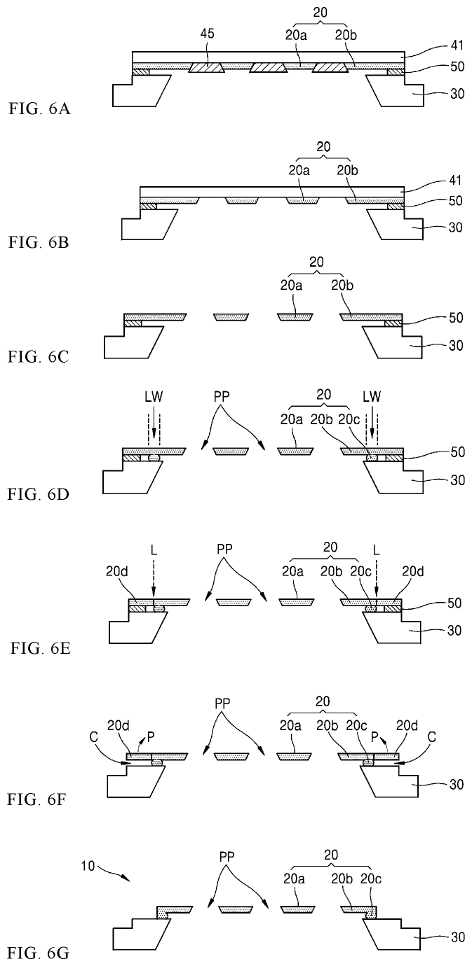

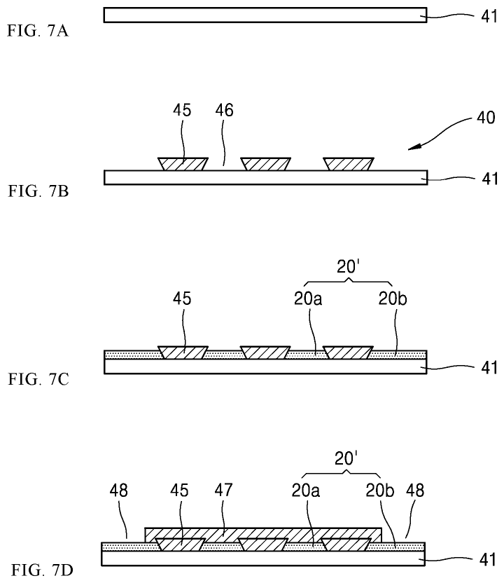

The present invention is characterized in that a mask 20 has a shape corresponding to a silicon wafer in order to perform a pixel deposition process on the silicon wafer as a target substrate 900 [see FIGS. 6A-6G and 7A-7D]. When the shape of the mask 20 corresponds to the silicon wafer, it means that the mask 20 has a shape having the same size as that of the silicon wafer or that the mask 20 is different in size from the silicon wafer but has the same shape and is coaxial to the silicon wafer. In addition, the mask 20 that has a shape corresponding to the silicon wafer is characterized in that it is integrally connected to the frame 30 and is thereby clearly aligned.

Referring to FIG. 2, the frame-integrated mask 10 may include a mask 20 and a frame 30 and the mask 20 may be attached to a part of a surface of the frame 30. A part of the mask 20 which is not attached to the frame 30 and has mask patterns DB and PP formed thereon is a mask body portion 20a and a part which is attached to a part of the frame 30 is a mask support portion 20b. Although the mask body portion 20a and the mask support portion 20b have different names and reference numerals according to the formed positions thereof, the mask body portion 20a and the mask support portion 20b are not separated regions and are configured to be integrally formed with the same material. In other words, the mask body portion 20a and the mask support portion 20b are each part of a plated film or the mask 20 (20a and 20b) which are electrodeposited and simultaneously formed in an electroforming process of forming the mask 20. Hereinafter, the mask body portion 20a and the mask support portion 20b may be used interchangeably with the plate film or the mask 20 (20a and 20b).

The mask 20 is preferably made of an Invar or Super Invar material and may have a circular shape to correspond to the circular silicon wafer. The mask 20 may have a size corresponding to a silicon wafer of 200 mm, 300 mm, 450 mm, or the like.

A conventional mask has a shape of rectangle, polygon, or the like to correspond to a substrate of a large area. In addition, a frame also has a shape of rectangle, polygon, or the like to correspond to the mask. Since the mask has angled corners, there may be a problem in that stress is concentrated on the corners. Concentration of stress may cause different force to act on only a portion of the mask, which may twist or distort the mask, leading to a failure of pixel alignment. In particular, at an ultra-high resolution of 2000 PPI or above, stress concentration on the corners of the mask should be avoided.

Accordingly, as the mask 20 of the present invention has a circular shape, the mask 20 does not have any corners. Since there is no corner, it is possible to solve the problem that different force acts on a specific portion of the mask 20, and the stress may be uniformly distributed along a circular edge. Accordingly, the mask 20 is not twisted or distorted and contributes to clear pixel alignment, and mask patterns PP of 2000 PPI or above may be implemented. The present invention performs a pixel deposition process by matching a circular silicon wafer having a low coefficient of thermal expansion and the circular mask 20 in which the stress is uniformly distributed along the edge, so that pixels with a size of approximately 5 to 10 μm may be deposited.

Referring to (a) of FIG. 3, a plurality of display patterns (DP) may be formed in the mask body portion 20a. Each of the display patterns DP may be a pattern that corresponds to one microdisplay, and may have a diagonal length of approximately 1 to 2 inches. A plurality of pixel patterns PP that correspond to red (R), green (G), and blue (B) pixels are shown when the display pattern DP is magnified. Sides of each pixel pattern PP may have a sloped shape, a tapered shape, or a shape in which a pattern width gradually increases from the upper portion toward the lower portion. Various pixel patterns PP may be grouped to form a single display pattern DP, and a plurality of display patterns DP may be formed in the mask 20.

That is, in this specification, the display pattern DP does not indicate a single pattern and should be understood as a group of a plurality of pixel patterns PP corresponding to a single display. Hereinafter, the pixel pattern PP will be used interchangeably with the mask pattern PP.

The mask pattern PP may have a substantially tapered shape, and the pattern width may be a several to several tens of and preferably of approximately 5 to 10 μm (resolution of 2000 PPI or above). The mask pattern PP may be formed by patterning through a photoresist (PR) [see FIGS. 5A-5C], laser processing, and the like, but is not limited thereto. The mask pattern PP has the same structure as the pixel pattern PP/display pattern DP described above with reference to FIG. 3.

The frame 30 may be connected to the mask 20 or to at least a part of the plated film 20. In more detail, the mask support portion 20b, which is a region other than the mask body portion 20a that is a region where the mask pattern PP is formed in the mask 20, may be connected to the frame 30.

The frame 30 preferably has a shape surrounding the edge of the mask 20 such that the mask 20 is supported taut without sagging or twisting.

In more detail, the frame 30 may include a connecting frame 31 connected to the mask 20 and a support frame 35 integrally connected to the connecting frame 31 at a lower portion of the connecting frame 31 and supporting the mask 20 and the connecting frame 31.

The connecting frame 31 is preferably in a circular shape such that it corresponds to the shape of the mask 20 and can be connected to the edge [the mask support portion 20b] of the mask 20, and the connecting frame 31 has a hollow shape or a ring shape so as not to cover the mask pattern PP of the mask body portion 20a. That is, the connecting frame 31 may have a circular ring shape. Meanwhile, if the support frame 35 is integrally connected to the connecting frame 31 at the lower portion of the connecting frame 31, the support frame 35 may have various shapes, such as a circular ring shape, a rectangular ring shape, and the like, as long as a center portion of the support frame 350 is empty. In the present invention, the support frame 35 is illustrated as having a rectangular ring shape.

Referring to FIGS. 2 and 4, the width W of the mask 20 [the masking support portion 20b] adhered to the connecting frame 31 may be constant along an outer circumferential direction of the mask 20. That is, the area where all edges [the mask support portion 20b] of the circular mask 20 and the connecting frame 31 are attached to each other may be constant. Since the area to which the connecting frame 31 is attached is constant in all edges of the mask 20, the effect of uniform stress distribution is obtained, and as the mask 20 is formed in a circular shape, the effect of uniform stress distribution may be further enhanced.

Alternatively, the mask 20 may be integrally connected to the frame 30 [the connecting frame 31] in a state in which a tensile force F is exerted on an outer circumference [the mask support portion 20b] of the mask 20 in a direction of the frame. The direction of the frame may correspond to a direction perpendicular to a circumferential tangent of the mask 20 or a radial direction. The tensile force F may be caused by electroforming process conditions by which the mask 20 is integrally electrodeposited on the frame 30 and by shrinkage of the mask 20 due to a temperature difference caused by a temperature drop to room temperature after electrodeposition at a temperature higher than the room temperature. Since the tensile force F is exerted on the outer circumference of the mask 20 in a radial direction, the tensile force F may prevent the stress from being concentrated on a specific portion of the outer circumference of the mask 20, and enable the mask 20 and the frame 30 to be connected to each other while kept taut, thereby contributing to maintaining the alignment of the mask patterns PP.

In addition, in the frame-integrated mask 10 of the present invention, the mask 20 is integrally connected to the frame 30 and thus the alignment of the mask 20 may be completed by only a process of moving and installing the frame 30 in the OLED pixel deposition apparatus 200.

FIGS. 5A-5C and 6A-6G are schematic diagrams showing a process of manufacturing a frame-integrated mask according to one embodiment of the present invention.

Referring to FIG. 5A, a conductive substrate 41 is prepared to perform electroforming. A mother plate 40 including the conductive substrate 41 may be used as a cathode body in electroforming. In order to electroform a circular mask 20, the conductive substrate 41 is preferably in a circular shape corresponding to the mask 20, but is not limited thereto. Even when the conductive substrate 41 is a polygon, rather than of a circular shape, laser trimming into a circular shape may be performed [see FIG. 6E] after the mask 20 is adhered to a frame 30 [see FIG. 6A].

As a conductive material, a metal may have metal oxides on the surface thereof and impurities may be introduced during a metal substrate manufacturing process, a polycrystalline silicon substrate may have an intervening product or a grain boundary, and a conductive polymer substrate may have a high probability of containing impurities and have low strength and acid resistance. Elements which hinder uniform generation of an electric field on the surface of the mother plate 40, e.g., the metal oxides, the impurities, the intervening product, and the grain boundary, are referred to as “defects”. Due to the defects, an electric field may not be uniformly applied to the cathode body made of the above-described material and thus a part of the plated film 20 may be non-uniformly formed. In addition, in the case of a polycrystalline substrate material, a position of a pattern formed on the mask may be changed due to the non-uniformity between the grains by a heat treatment process for reducing a coefficient of thermal expansion of an electroformed plated film, which may lead to the change in a deposition position of a pixel.

In implementing ultra-high-resolution pixels of an ultra-high definition (UHD) or higher level, non-uniformity of the plated film 20 and plated film patterns PP may exert bad influence on deposition of pixels. An FMM mask or a shadow mask may have a pattern width of several to several tens of μm, and preferably, approximately 5 to 10 μm (resolution of 2000 PPI or above), and thus even defects of several μm may take up a significant proportion of the size of the mask.

In addition, a process for removing, for example, metal oxides and impurities may be additionally performed to remove defects from the cathode body made of the above-described material, and in this process, other defects, e.g., etching of the cathode material, may be caused.

Therefore, the present invention may use the substrate 41 made of monocrystalline silicon. To achieve conductivity, the substrate 41 may be highly doped at a concentration equal to or higher than 1019. The doping may be performed on the entire substrate 41 or on only the surface of the substrate 41.

The doped monocrystalline silicon has no defects and thus the uniform plated film 20 [or the mask 20] having no surface defects may be formed due to generation of a uniform electric field on a whole surface in an electroforming process. The uniform mask 20 may increase the resolution of OLED pixels. Moreover, since a process for removing or preventing defects is not additionally required, process costs may be reduced and productivity may be increased.

In addition, since the substrate 41 made of silicon is used, an insulator 45 may be formed, when necessary, by merely oxidizing or nitriding the surface of the substrate 41. The insulator 45 may prevent electrodeposition of the plated film 30 to form patterns PP of the plated film 20.

Subsequently, referring to FIG. 5B, the insulator 45 may be formed on at least one surface of the substrate 41. The insulator 45 may be formed with patterns and the patterns may be engraved patterns 46 having a tapered or inverse-tapered shape. The insulator 45 is a part formed to protrude (embossed) from one surface of the substrate 41, and may have an insulation property. Accordingly, the insulator 45 may be made of at least one of a photoresist material, a silicon oxide material, and a silicon nitride material. The insulator 45 may be formed by forming a silicon oxide or a silicon nitride on the substrate 41 using deposition or the like, and thermal oxidation or thermal nitridation may be used using the substrate 41 as a base. A photoresist may be formed using a printing method or the like. When the patterns are formed using a photoresist, a multiple exposure method, a method of varying an exposure intensity per region, or the like may be used. The insulator 45 may have a thickness of approximately 5 to 20 μm such that it is thicker than the plated film 20, which will be described below. As such, the mother plate 40 may be manufactured.

The plated film 20 may be formed from an exposed surface of the substrate 41 in the electroforming process, which will be described below, and the generation of plated film 20 is prevented in a region where the insulator 45 is to be disposed, so that the patterns PP may be formed. Since the patterns can be formed in the process of generating the plated film 20, the mother plate 40 may also be referred to as a “mold” or a “cathode body”.

Subsequently, referring to FIG. 5C, an anode body (not shown) facing the mother plate 40 [or the cathode body 40] is prepare. The anode body (not shown) may be dipped in a plating solution (not shown), and the entire or a part of the mother plate 40 may be dipped in the plating solution (not shown). A plated film 20 (20a and 20b) may be electrodeposited on the surface of the mother plate 40 due to an electric field generated between the mother plate 40 [or the cathode body 40] and the facing anode body. However, since the plated film 20 is formed on an exposed part of the surface of the substrate 41 and is not formed on the surface of the insulator 45, patterns PP [see (b) of FIG. 3] may be formed in the plated film 20.

A plating solution is an electrolyte and may serve as a material of the plated film 20 to constitute a mask body portion 20a and a mask support portion 20b. According to an embodiment, when an Invar thin film made of an iron (Fe)-nickel (Ni) alloy is manufactured as the plated film 20, a mixture of a solution including Ni ions and a solution including Fe ions may be used as the plating solution. According to another embodiment, when a Super Invar thin film made of a Fe—Ni-cobalt (Co) alloy is manufactured as the plated film 20, a mixture of a solution including Ni ions, a solution including Fe ions, and a solution including Co ions may be used as the plating solution. The Invar thin film or the Super Invar thin film may be used as an FMM mask or a shadow mask in an OLED manufacturing process. Since the Invar thin film has a very low thermal expansion coefficient of approximately 1.0×10-6/° C. or the Super Invar thin film also has a very low thermal expansion coefficient of approximately 1.0×10-7/° C., mask patterns may not be easily deformed by heat energy and thus the Invar thin film or the Super Invar thin film may be commonly used in a high-resolution OLED manufacturing process. The plating solution for a desired plated film 20 is not particularly limited and the following description will be focused on manufacturing of the Invar thin film 20.

Since the plated film 20 grows in thickness from the surface of the substrate 41 as the plated film 20 is electrodeposited, the plated film 20 is preferably formed such that it does not grow beyond a top surface of the insulator 45. That is, the thickness of the plated film 20 may be less than the thickness of the insulator 45. Since the plated film 20 is electrodeposited by filling up pattern spaces of the insulator 45, the plated film 20 may be formed with a tapered shape which is reverse to the shape of the pattern of the insulator 45.

Since the insulator 45 has an insulation property, a magnetic field is not formed between the insulator 45 and the anode body, or only a weak magnetic field in which plating is difficult to perform is formed. Thus, a part of the mother plate 40 where the plated film 20 is not formed and which corresponds to the insulator 45 constitutes a pattern of the plated film 20, a hole, or the like. In other words, each of the insulators 45 which are patterned 46 may form a mask pattern PP that corresponds to R, G, or B of the mask body portion 20a. A shape of a vertical cross-sectional surface of the mask pattern PP may be sloped in a substantially tapered shape, and a slope angle may be approximately 45° to 65°.

Alternatively, heat treatment may be performed on the plated film 20 after the plated film 20 is formed. The heat treatment may be performed at a temperature of 300° C. to 800° C. Generally, an Invar thin plate produced by electroforming has a higher coefficient of thermal expansion as compared to an Invar thin plate produced by rolling. Thus, by performing heat treatment on the Invar thin plate, the coefficient of thermal expansion can be lowered. In this heat treatment, slight deformation may occur in the Invar thin plate. Hence, when heat treatment is performed in a state where the mother plate 40 [or the substrate 41] and the mask 20 are attached to each other, the shape of the mask pattern PP formed in a space portion occupied by the insulator 45 of the mother plate 40 is maintained constant and the minute deformation due to the heat treatment may be advantageously prevented. In addition, even when the heat treatment is performed on the mask 20 having the mask pattern PP after the mother plate 40 [or the substrate 41] is separated from the plated film 20, there is an effect of lowering the coefficient of thermal expansion of the Invar thin film.

Therefore, as the coefficient of thermal expansion of the mask 100 is further lowered, the mask 20 capable of preventing deformation of the μm-scale pattern PP and depositing ultra-high-resolution OLED pixels may be advantageously manufactured.

Subsequently, referring to FIG. 6A, the mother plate 40 [or the cathode body 40] is lifted out of a plating solution (not shown). In addition, a structure of FIG. 5C is placed upside down on the frame 30. On the contrary, the frame 30 may be placed upside down on the structure of FIG. 5C. The frame 30 [a connecting frame 31] may have a shape surrounding the plated film 20.

An adhesive portion 50 may be formed on the frame 30 [the connecting frame 31] in contact with the plated film 20. An epoxy resin adhesive or the like may be used as an adhesive of the adhesive portion 50. At least a part of the edge of the plated film 20 may be adhesively fixed on the frame 30 [the connecting frame 31] by the adhesive portion 50.

Then, referring to FIG. 6B, the insulator 45 may be removed. A known technique that removes only the insulator 45, such as a photoresist, a silicon oxide, a silicon nitride, and the like, and does not affect the rest of the configuration may be used without limitation. In a case where the insulator is formed with a silicon oxide or a silicon nitride, a step of removing the insulator may be omitted and the following process shown in FIG. 6C may be immediately performed. The silicon oxide or silicon nitride which is formed integrally on the conductive substrate 41 may be simultaneously separated/removed through the process of separating the substrate 41 illustrated in FIG. 6C.

Then, referring to FIG. 6C, the conductive substrate 41 may be separated from the plated film 20. The conductive substrate 41 may be separated in an upward direction of the mask 20 and the frame 30. Once the conductive substrate 41 is separated, the shape of the mask 20 adhered to the frame 30 via the adhesive portion 50, which is interposed between the mask 20 and the frame 30, appears.

In the case of the structure which has undergone the step shown in FIG. 6C, the adhesive portion 50 remains essentially in order to adhere the mask 20 to the frame 30. Although the adhesive of the adhesive portion 50 has an effect of temporarily fixing the mask 20, the adhesive may distort the mask 20 in the pixel formation process according to the temperature change since the coefficients of thermal expansion of the adhesive and the Invar mask 20 are different. In addition, contaminants generated by a reaction of the adhesive with a process gas may adversely affect OLED pixels, and outgassing of, for example, organic solvents or the like contained in the adhesive itself may contaminate a pixel process chamber or be deposited on the OLED pixels as impurities. Moreover, there may be a problem in that the mask 20 is separated from the frame 30 as the adhesive is gradually removed. Accordingly, the adhesive portion 50 needs to be cleaned, but it is difficult to clean the adhesive part 50 from the outside since the adhesive portion 50 and the mask support part 20b are adhered to each other. Also, there is a possibility of deformation in the mask 20 while forcibly cleaning the adhesive portion 50. Furthermore, when the adhesive part 50 has been cleaned and removed, another method for integrally bonding the mask 20 and the frame 30 needs to be devised.

Thus, the present invention may perform processes, such as FIG. 6D to FIG. 6F to completely remove the adhesive portion 50 without affecting the mask 20. Also, the present invention may provide a frame-integrated mask 10 in which the mask 20 and the frame 30 are integrally bonded via a welded portion 20c, which is interposed between the mask 20 and the frame 30, in replace of the adhesive portion 50.

Referring to FIG. 6D, by using a plated film 20b on the edge portion, laser welding may be performed between the plated film 20b and the frame 30. When a laser beam is irradiated to an upper part of the mask support portion 20b on the edge portion, a part of the mask support portion 20b may be melted so that the welded portion 20c may be formed. Specifically, the laser beam is required to be irradiated to an inner region than a region where the adhesive portion 50 is formed. The welded portion 20c must be formed in the inner region than the adhesive portion 50 because the adhesive 50 must be removed by infiltrating cleaning fluid from the outer side of the frame 30 [or an outer surface of the plated film 20] in a subsequent process. In addition, the welded portion 20c should be formed close to the corner of the frame 30 to reduce a floating gap between the plated film 20 and the frame 30 as much as possible and to increase the adhesion. The welded portion 20c may be generated in the form of a line or a spot and be a medium that is made of the same material as the plated film 20b and integrally connects the plated film 20b and the mask 20. For the convenience of description, the welded portion 20c is illustrated as being somewhat thick in FIGS. 6D-6G, but it is noted that the thickness of the welded portion 20c is negligibly small and does not affect the thickness of the plated film 20b.

When the plated film 20 is adhered to the adhesive portion 50 in step FIG. 6A, the plated film 20 may be adhered in a state in which the plated film 20 is subjected to a tensile force in the direction of the frame 30 or in the outward direction. The mask 20 which is accordingly pulled taut toward the frame 30 may be temporarily adhered to the frame 30. In this state, when laser welding LW as shown in FIG. 6D is performed, the mask 20 may be welded to the upper part of the frame 30 [the connecting frame 31] in a state where the mask 20 is subjected to an outward tensile force. Thus, even when the adhesive portion 50 is removed in a subsequent process, the tensile force is applied in the outward direction and the state of being pulled taut toward the frame 30 may be maintained.

Subsequently, referring to FIG. 6E, a separation line may be formed between the plated film 20b and a release film 20d by irradiating a laser beam L to a boundary of a region of the plated film 20 that corresponds to the adhesive portion 50. That is, as laser trimming is performed on the plated film 20b by irradiating a laser beam L onto a boundary of the release film 20d, the release film 20d may be separated from the plated film 20. However, the release film 20d is not immediately peeled off, but remains adhered to the adhesive portion 50.

Then, referring to FIG. 6F, the adhesive portion 50 may be cleaned (C). A known cleaning material may be used without limitation depending on the adhesive, and the adhesive portion 50 may be cleaned (C) by infiltrating known cleaning fluid from the side of the plated film 20. As such, the adhesive portion 50 may be completely removed.

Subsequently, the release film 20d separated from the plated film 20 is peeled off (P). The release film 20d is not adhered to the frame 30 by removal of the adhesive portion 50 and is separated from the plated film 20, and thus may be immediately peeled off.

Then, referring to FIG. 6G, the frame-integrated mask 10 in which the mask 20 and the frame 30 are integrally formed is completed. The frame-integrated mask 10 of the present invention has no adhesive portion 50, and only a part [the release film 20d] of the edge 20b of the plated film 20 is removed to remove the adhesive portion 50, so that the plated film 20, which contributes to a pixel process, is not affected at all.

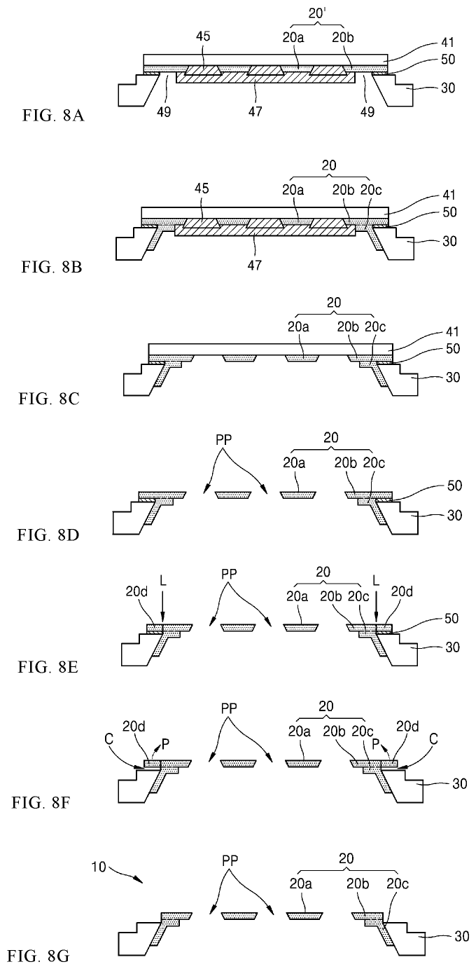

FIGS. 7A-7D and 8A-8G are schematic diagrams showing a process of manufacturing a frame-integrated mask according to another embodiment of the present invention.

FIG. 7A to FIG. 7C are the same as FIG. 5A to FIG. 5C, and hence detailed descriptions thereof will be omitted.

Referring to FIG. 7D, a mother plate 40 [or a cathode body 40] is lifted out of a plating solution (not shown). Then, a second insulator 47 may be formed. The second insulator 47 is preferably made of the same material as a first insulator 45. The second insulator 47 may be formed on a region, excluding an edge region 48 of a first plated film 20′. That is, the second insulator 47 may cover all of the first insulator 45 and the first plated film 20′ and cover a part of a first plated film edge 20b. The edge region 48 of the first plated film 20′ may be exposed.

Then, referring to FIG. 8A, the structure of FIG. 7D is placed upside down on the frame 30. On the contrary, the frame 30 may be placed upside down on the structure of FIG. 7D. The frame 30 may have a shape surrounding the plated film 20′. Preferably, the frame 30 may have a shape that corresponds to the remaining edge region 48 other than an exposed region 49 of the first plated film 20′.

An adhesive portion 50 may be formed on an upper portion of the frame 30 [a connecting frame 31] in contact with the first plated film 20′. An epoxy resin adhesive or the like may be used as an adhesive of the adhesive portion 50. At least a part of the edge of the plated film 20 may be adhesively fixed on the frame 30 [the connecting frame 31] by the adhesive portion 50. An edge portion of the first plated film 20′ attached to the adhesive portion 50 is later removed, and hence is referred to as a “release film” 20d [see FIG. 8E]. Also, for convenience of description, widths of the adhesive portion 50 and the release film 20d illustrated are somewhat exaggerated. It suffices that the adhesive portion 50 is coated to a degree which allows the first plated film 20′ to be temporarily fixed to the frame 30 before forming a second plated film 20c.

Then, referring to FIG. 8B, the second plated film 20c may be electrodeposited by performing electroforming. The second plated film 20c may be electrodeposited on a surface 49 of the first plated film 20′ exposed between the second insulator 47 and the adhesive portion 50 and an inner side surface of the frame 30. Since the second plated film 20c grows in thickness from the exposed surface 49 of the first plated film 20′ as the plated film 20 is electrodeposited, the second plated film 20c is preferably formed such that it does not grow beyond a top surface of the second insulator 47. That is, the thickness of the second plated film 20c may be less than the thickness of the second insulator 47. The second plated film 20c is electrodeposited on the exposed surface 49 of the first plated film 20′ and the inner side surface of the frame 30 to serve as a medium that integrally connect the first plated film 20′ and the frame 30. In this case, since the second plated film 20c is integrally connected to the edge 20b of the first plated film 20′ and is electrodeposited, the second plated film 20c may support the first plated film 20′ while applying a tensile force in a direction of the frame 30 [in a direction of the inner side of the frame 30] or in an outward direction. Accordingly, the mask 20, which is pulled taut toward the frame 30, may be integrally formed with the frame 30 without a need of separately performing a process of tensioning and aligning the mask.

After the first plated film 20a and 20b and the second plated film 20c are formed, heat treatment may be performed on the first plated film 20a and 20b and the second plated film 20c.

Then, referring to FIG. 8C, the first insulator 45 and the second insulator 47 may be removed. A known technique that removes only the first insulator 45 and the second insulator 47, such as a photoresist, a silicon oxide, a silicon nitride, and the like, and does not affect the rest of the configuration may be used without limitation. In a case where the insulator is formed with a silicon oxide or a silicon nitride, a step of removing the insulator may be omitted and the following process shown in FIG. 8D may be immediately performed. The silicon oxide or silicon nitride which is formed integrally on the conductive substrate 41 may be simultaneously separated/removed through a substrate separation process illustrated in FIG. 8D.

Subsequently, referring to FIG. 8D, the conductive substrate 41 may be removed from the first plated film 20′. The conductive substrate 41 may be separated in an upward direction of the mask 20 and the frame 30. When the conductive substrate 41 is separated, a shape appears in which the mask 20 and the frame 30 supporting the mask 20 are integrally formed.

Meanwhile, the adhesive portion 50 remains on the frame-integrated mask which has undergone the step of FIG. 8D. The effects and problems of the adhesive portion 50 are the same as those described above with reference to FIGS. 6A-6E. Thus, the present invention may perform the steps of, for example, FIG. 8E and FIG. 8F to completely remove the adhesive portion without affecting the plated film 20.

Referring to FIG. 8E, a separation line may be formed between the first plated film 20′ and the release film 20d by irradiating a laser beam (L) to a boundary of a region of the first plated film 20′ that corresponds to the adhesive portion 50. That is, the laser trimming is performed on the first plated film 20′ by irradiating the laser beam L to the boundary of the release film 20d, so that the release film 20d may be separated from the first plated film 20′. However, the release film 20d is not immediately peeled off, but remains adhered to the adhesive portion 50.

Then, referring to FIG. 8F, the adhesive portion 50 may be cleaned (c). Depending on the adhesive, a known cleaning material may be used without limitation, and the adhesive portion 50 may be cleaned (C) by infiltrating known cleaning fluid from the side of the plated film 20. As such, the adhesive portion 50 may be completely removed.

Subsequently, the release film 20d separated from the first plated film 20′ is peeled off. The release film 20d is not adhered to the frame 30 by removal of the adhesive portion 50 and is separated from the plated film 20′, and thus may be immediately peeled off.

Then, referring to FIG. 8G, a frame-integrated mask 10 in which the mask 20 and the frame 30 are integrally formed is completed. The frame-integrated mask 10 of the present invention has no adhesive portion 50, and only a part [the release film 20d] of the edge 20b of the plated film 20′ is removed to remove the adhesive portion 50, so that the plated film 20a and 20b and the second plated film 20c, which contribute to a pixel process, are not affected at all.

In order to ensure rigidity of the frame 30 and to have a coefficient of thermal expansion similar to that of the mask 20, the frame 30 is preferably made of a metal material, such as Invar, Super Invar, SUS, Ti, or the like, which has conductivity, and more preferably, the same Invar or Super Invar material as that of the mask 20. Also, it is preferable to use a material having a small thermal strain in order to prevent deformation of the frame 30 due to heat in the OLED pixel deposition process.

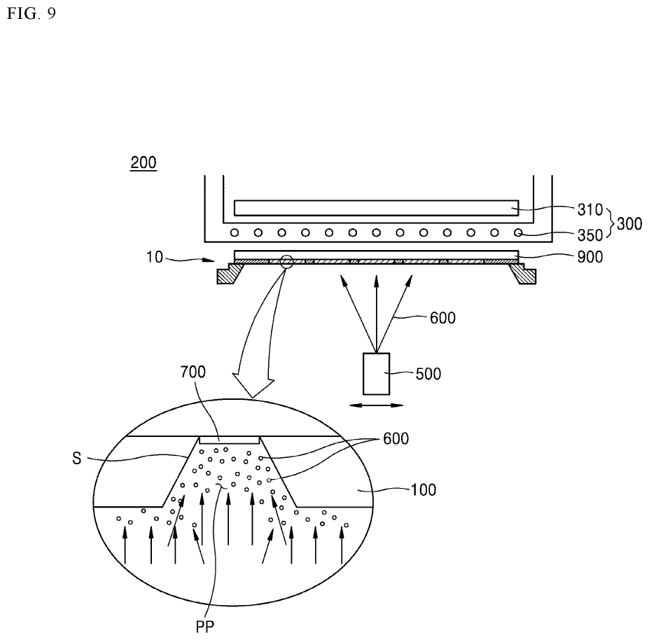

FIG. 9 is a schematic diagram illustrating an OLED pixel deposition apparatus to which the frame-integrated mask of FIG. 2 is applied.

Referring to FIG. 9, alignment of the mask 10 may be completed by bringing the frame-integrated mask 10 in contact with the target substrate 900, which is a silicon wafer, and fixing only the frame 30 to the inside of the OLED pixel deposition apparatus 200. A circular mask 20 is integrally connected to the connecting frame 31 and is taut supported at an edge thereof, and the stress is uniformly distributed over the edge, and thus deformation, such as sagging or twisting with the load, may be prevented. Accordingly, clear alignment of the mask 10 necessary for pixel deposition may be achieved.

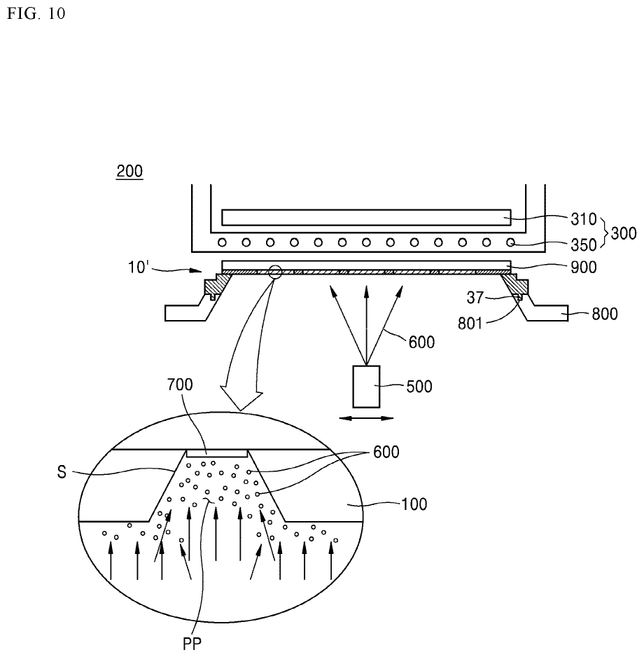

FIG. 10 is a schematic diagram showing a state in which a frame-integrated mask in accordance with another embodiment of the present invention is applied to an OLED pixel deposition apparatus.

Referring to FIG. 10, the frame-integrated mask 10′ may include a circular mask 20 and a frame 30 integrally connected to the mask. This point is the same as the frame-integrated mask 10 of FIG. 2. The frame-integrated mask 10′ differs from the frame-integrated mask 10 of FIG. 2 in that, unlike the frame 30 [see FIGS. 3 and 9], a support frame 35 of the frame-integrated mask 10 is not immediately fixedly installed inside the OLED pixel deposition apparatus 200, but is inserted into a recess 801 of a frame 800 fixedly installed inside the OLED pixel deposition apparatus 200.

The support frame 35 may further include a protruding portion 37 which can be inserted into the recess 801, and the manufactured frame-integrated mask 10′ may be inserted into the recess 801 of the frame 800 fixedly installed inside the OLED pixel deposition apparatus 200. The recess 801 may be formed in a shape that corresponds to the support frame 35 or the protruding portion 37 formed on a plurality of frame-integrated masks 10′.

The recess 801 of the pre-installed frame 800 may serve as a guide rail, so that alignment of the mask may be completed by simply inserting and sliding the manufactured frame-integrated mask 10′ into the recess 801 and sliding the frame-integrated mask 10′. In one example, the rectangular-shaped support frame 35 may be firmly fixed without moving. In another example, in a case where a pair of linear support frames 35 in parallel with each other is provided, the support frames 35 may be inserted into the recess 801 in a sliding manner, and the plurality of frame-integrated masks 10′ may be pushed and arranged in a sliding manner.

As such, the frame-integrated mask 10 or 10′ of the present invention includes the mask 20 having a shape that corresponds to a silicon wafer, so that stress is uniformly distributed over the edge of the mask 20, thereby providing ultrafine mask patterns PP, and ultra-high-resolution pixels at 2000 PPI or above may be realized in a microdisplay. Also, in the frame-integrated mask 10 or 10′ of the present invention, the mask 20 is integrally formed with the frame 30 and is integrally connected to the connecting frame 31 having a shape corresponding to the mask 20 such that the stress can be uniformly distributed, thereby preventing deformation of the mask 20 and achieving clear alignment. Also, in the frame-integrated mask 10 or 10′ of the present invention, the mask 20 is integrally connected to the frame 30, and hence alignment of the mask 20 may be completed through processes of moving the frame 30 to the OLED pixel deposition apparatus 200 and installing the frame 30.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A method of manufacturing a frame-integrated mask which is used in a process of forming pixels on a silicon wafer, the method comprising the steps of:
(a) preparing a substrate to which a first surface of a mask including a plurality mask patterns is attached;
(b) attaching an edge portion of a second surface facing the first surface of the mask to a frame by interposing an adhesive portion between the substrate and the frame;
(c) separating the substrate from the mask; and
(d) welding and adhering the mask to the frame,
wherein the frame comprises a connecting frame having a circular ring shape connected to the mask; and a support frame connected to a lower portion of the connecting frame and supporting the connecting frame, and
wherein the step (d) comprises welding and adhering the mask to the frame by irradiating a laser beam to a region positioned inner than a region in which the adhesive portion is formed.

2. The method of claim 1, wherein the step (a) comprises
(a1) preparing a conductive substrate having an insulator formed on the first surface and
(a2) forming a plated film on an exposed surface of the substrate to manufacture the mask including the plurality of mask patterns.

3. The method of claim 1, wherein in the step (b), the mask is attached to the frame in a state of being subjected to a tensile force in an outward direction, and after the step (d), the state in which the mask is subjected to the tensile force in the outward direction is maintained.

4. The method of claim 1, further comprising:
(e) performing laser trimming on an edge portion of the mask by irradiating a laser beam between the region in which the adhesive portion is formed and a region to which the mask and the frame are attached; and
(f) peeling off the trimmed edge portion of the mask by cleaning the adhesive portion.

5. The method of claim 1, further comprising:
(e) forming a separating line by performing laser trimming on a boundary portion between the adhesive portion and a welded portion, and removing a mask portion outside the separating line.

6. A frame-integrated mask which is used in a process of forming pixels on a silicon wafer, the frame-integrated mask comprising:
a mask having a circular shape corresponding to a silicon wafer and including a mask pattern; and
a frame connected to a least a part of a region of the mask excluding a region in which the mask pattern is formed,
wherein the frame comprises a connecting frame having a circular ring shape connected to the mask and a support frame connected to a lower portion of the connecting frame and supporting the connecting frame, and
wherein an outer circumference of the mask is formed by laser trimming and an welded portion that mutually attaches a lower surface of the mask and an upper surface of the connecting frame is formed in a region that is positioned at least inner than the outer circumference of the mask formed by laser trimming.

7. The frame-integrated mask of claim 6, wherein the welded portion is in the form of a line or a spot in a circumferential direction.
